(19) United States
(12) Patent Application Publication
(10) Pub. No.: US 2018/0157297 A1
(43) Pub. Date: Jun. 7, 2018

(54) THERMAL MANAGEMENT IN ELECTRONICS WITH METALLURGICALLY BONDED DEVICES

(71) Applicant: Microsoft Technology Licensing, LLC, Redmond, WA (US)

(72) Inventors: Andrew Douglas Delano, Woodinville, WA (US); Nicholas Wendt, Seattle, WA (US)

(21) Appl. No.: 15/446,354

(22) Filed: Mar. 1, 2017

Related U.S. Application Data
(60) Provisional application No. 62/431,270, filed on Dec. 7, 2016.

(51) Int. Cl. G06F 1/20; H05K 7/20; G06F 1/16

(52) U.S. Cl. CPC G06F 1/206; H05K 7/2039; H05K 7/20218; H05K 7/20336; G06F 1/1601

(57) ABSTRACT

Thermal management devices and methods are making are described herein. In one example, the thermal management device includes a heat spreader having a first surface and a second surface, wherein the first surface of the heat spreader is configured to be positioned adjacent to a heat source of an electronic device. The thermal management device also includes a heat dissipation device configured to dissipate heat from the heat source, wherein at least a portion of the second surface of the heat spreader is metallurgically bonded with at least a portion of a surface of the heat dissipation device.

### CROSS-REFERENCE TO RELATED APPLICATIONS

This application claims the benefit of U.S. Provisional Patent Application No. 62/431,270, filed Dec. 7, 2016, herein incorporated by reference in its entirety.

### BACKGROUND

Current microprocessor design trends include designs having an increase in power, a decrease in size, and an increase in speed. This results in higher power in a smaller, faster microprocessor. Another trend is towards lightweight and compact electronic devices. As microprocessors become lighter, smaller, and more powerful, they also generate more heat in a smaller space, making thermal management a greater concern than before.

The purpose of thermal management is to maintain the temperature of a device within a moderate range. During operation, electronic devices dissipate power as heat, which must be removed from the device. Otherwise, the electronic device will get hotter and hotter until it fails, reducing its service life. Short of failure, electronic devices run slowly and dissipate power poorly at high temperatures.

### SUMMARY

Heat dissipation devices and methods are described herein. In one or more embodiments, a thermal management device is provided. The device includes a heat spreader having a first surface and a second surface, wherein the first surface of the heat spreader is configured to be positioned adjacent to a heat source of an electronic device. The thermal management device further includes a heat dissipation device configured to dissipate heat from the heat source, wherein at least a portion of the second surface of the heat spreader is metallurgically bonded with at least a portion of a surface of the heat dissipation device.

In another embodiment, an electronic device is provided. The electronic device includes a display module, a backing layer, and a processor positioned between the display module and the backing layer. The electronic device further includes a heat spreader positioned between the display module and the backing layer, the heat spreader having a first surface and a second surface, wherein the first surface of the heat spreader abuts a surface of the processor. The electronic device further includes a heat dissipation device configured to dissipate heat from the processor, wherein at least a portion of the second surface of the heat spreader is metallurgically bonded with at least a portion of a surface of the heat dissipation device.

In another embodiment, a method is provided for making a thermal management device. The method includes providing a heat spreader and a heat dissipation device, wherein the heat spreader is a metallic cold plate and the heat dissipation device is a vapor chamber, heat fin, heat tube, or heat sink. The method also includes metallurgically bonding at least a portion of a surface of the heat spreader with at least a portion of a surface of the heat dissipation device, wherein no additional composition or material is used to bond the heat spreader and the heat dissipation device other than a composition of the heat spreader and a composition of the heat dissipation device.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DESCRIPTION OF THE DRAWING FIGURES

For a more complete understanding of the disclosure, reference is made to the following detailed description and accompanying drawing figures, in which like reference numerals may be used to identify like elements in the figures.

FIG. 1 depicts an example of a side-view of an electronic device having a thermal management device.

FIG. 2A depicts an example of a thermal management device.

FIG. 2B depicts an additional example of a thermal management device.

FIG. 2C depicts an example of a metallurgical bond between two components of a thermal management device.

FIG. 3 is a flow diagram of a method of making a thermal management device in accordance with one example.

FIGS. 4A, 4B, and 4C depict various stages of making a thermal management device in accordance with an example.

FIG. 5 is a block diagram of a computing environment in accordance with one example for implementation of the disclosed methods or one or more electronic devices.

While the disclosed devices, systems, and methods are representative of embodiments in various forms, specific embodiments are illustrated in the drawings (and are hereafter described), with the understanding that the disclosure is intended to be illustrative, and is not intended to limit the claim scope to the specific embodiments described and illustrated herein.

### DETAILED DESCRIPTION

Disclosed herein are thermal management devices, systems, and methods for improved heat dissipation from an electronic device. Such thermal management devices, systems, or methods have several potential end-uses or applications, including any electronic device having passive or active cooling. For example, the thermal management device may be incorporated into an electronic device such as a personal computer, server computer, tablet or other handheld computing device, laptop or mobile computer, communication device such as mobile phone, multiprocessor system, microprocessor-based system, set top box, programmable consumer electronic, network PC, minicomputer, mainframe computer, or audio or video media player. In certain examples, the thermal management device may be incorporated within a wearable electronic device, wherein the device may be worn on or attached to a person's body or clothing. The wearable device may be attached to a person's shirt or jacket; worn on a person's wrist, ankle, waist, or head; or worn over their eyes or ears. Such wearable devices may include a watch, heart-rate monitor, activity tracker, or head-mounted display.

Improved heat dissipation within an electronic device may be implemented by providing or forming a thermal management device having a heat spreader and a heat dissipation device, where there is a metallurgical bond between the heat spreader and the heat dissipation device. In some examples, the two components are metallurgically bonded together via magnetic pulse welding, explosion welding, friction welding, or pulsed laser welding.

Such a thermal management device is advantageous for several reasons. First, the combination of the two components via a metallurgical bond allows for coupling a softer, more conductive metal (e.g., copper) to spread the heat from the heat source with a stronger, lighter metal (e.g., titanium) for further dissipation of the heat. This allows for the construction of a thinner, lighter heat dissipation device relative to copper while maintaining or improving the thermal performance of the device.

Second, with the implementation of the metallurgical bonded components of the thermal management device, a more powerful microprocessor may be installed for the electronic device, a thinner or lighter electronic device may be designed, a higher processing speed may be provided, or a combination thereof when compared to a similar electronic device without one or more of the improved heat dissipation features. In other words, the heat dissipation features described herein may provide improved thermal management for an electronic device such as a mobile phone, tablet computer, or laptop computer.

Third, metallurgical bonding may limit or reduce any thermal penalty that may be present due to the dissimilar thermal properties between the heat spreader and the heat dissipation device. For example, poorer thermal properties of a titanium vapor chamber (as compared with a copper vapor chamber) may be avoided or reduced by metallurgically bonding the titanium vapor chamber with a copper heat spreader. This, in turn, may allow for maintained or improved performance of the electronic device within a smaller space.

Fourth, metallurgical bonding eliminates the use of a dangerous or costly chemical manufacturing process to join two dissimilar metals together.

As used herein, a “metallurgical bond” may refer to a chemical bond between two (e.g., dissimilar) metals that is free of voids, oxide films, or discontinuities. The metallurgical bond may include no additional compositions or materials to bond the two dissimilar metals together other than the compositions of the two metals themselves. As disclosed herein, the metallurgical bond may be formed by a solid-state welding process such as magnetic pulse welding, friction welding, explosion welding, or pulsed laser welding.

As used herein, “magnetic pulse welding” may refer to a solid-state welding process that uses magnetic forces to weld two (e.g., dissimilar) metals together. nth magnetic pulse welding, high quality welds in similar and dissimilar metals may be made in microseconds without the need for shielding gases or welding consumables. Additionally, magnetic pulse welding is advantageous in avoiding formation of a brittle intermetallic phase between the two metals.

As used herein, “friction welding” may refer to a solid-state welding process that generates heat through mechanical friction between two metals in relative motion to one another, with the addition of a lateral force called “upset” to plastically displace and fuse the materials. Because no melting occurs, friction welding is not a fusion welding process in the traditional sense, but more of a forge welding technique.

As used herein, “explosion welding” may refer to a solid-state welding process where welding is accomplished by accelerating one of the components at extremely high velocity using chemical explosives.

As used herein, “pulsed laser welding” may refer to a welding technique used to join two metals together using an intermittent or pulsed laser beam. The beam provides a concentrated heat source, allowing for narrow, deep welds and high welding rates. The beam may be pulsed or turned on an off at a predefined frequency of time. The energy of each beam, the peak power of a beam, the frequency of the pulse, the duration of the pulse, and the surface area of the applied pulse are all variables that may be optimized to create an effective metallurgical bond.

The devices and methods of forming the thermal management devices and electronic devices are described in greater detail below.

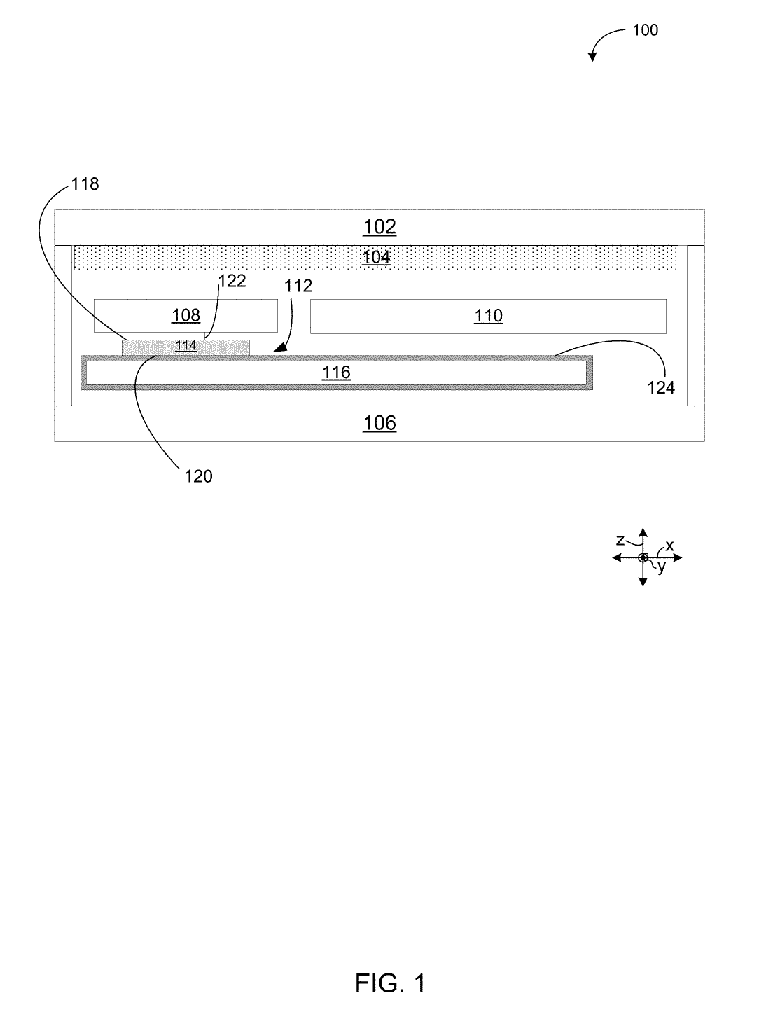

FIG. 1 depicts a non-limiting example of an electronic device 100 having a thermal management device. The electronic device 100 includes a display screen or display module 102. The display module 102 may be a touch display module. The display module 102 may include a light-emitting device such as a liquid crystal display (LCD) or a light emitting diode (LED) (e.g., an organic light emitting diode (OLED)). The LCD or LED may be disposed in, or configured as, a film. The configuration, construction, materials, and other aspects of the light emitting devices may vary. For instance, III-V semiconductor-based LED structures may be used to fabricate micron-sized LED devices. The small thickness of such structures allows the light emitting devices to be disposed in planar arrangements (e.g., on or in planar surfaces) and thus, distributed across the viewable area of the display. Non-LED technologies, such as finely tuned quantum dot-based emission structures, may also be used. Other thin form factor emission technologies, whether developed, in development, or future developed, may be used within the display module 102.

In certain examples, the display module includes a back plate 104. The back plate 104 may be bonded (e.g., adhesively bonded) to the LCD or LED. The back plate 104 may be made of a thermally conductive material such as stainless steel, copper, aluminum, gold, silver, tungsten, or a composite or an alloy thereof. In one example, the back plate 104 includes stainless steel. In another example, the back plate 104 includes aluminum. The conductivity of the back plate 104 may be advantageous because it may allow heat generated from the electronic device 100 to be dissipated along the length of the back plate 104, instead of in a localized region of the back plate 104.

The electronic device 100 further includes a backing layer 106 or chassis. The backing layer 106 is positioned on the rear end of the electronic device 100 such that the display module 102 and backing layer 106 bookend the internal components of the electronic device 100. The backing layer 106 may be made of any variety of materials now known or later developed such as metals, plastics, polymers, ceramics, or combinations thereof. The backing layer 106, for instance, may be formed from one or more sub-layers of a polymer or mixture of polymers. For example, the backing layer 106 may be formed from polymers such as thermoplastic polymers, silicones, or polyurethanes. In some examples, the backing layer 106 is formed from a polyurethane laminate, where a cloth fabric is laminated onto a thin film of polyurethane.

Positioned between the back plate 104 of the display module 102 and the backing layer 106 are the internal components of the electronic device 100. One internal component is a circuit board or motherboard 108. The circuit board 108 may be a printed circuit board or a flexible circuit board. The circuit board 108 may be configured to hold and allow communication between one or more central processing units (CPUs), graphics processing units (GPUs), and memories. The circuit board 108 may also be configured to provide connections to sound cards, video cards, network cards, hard drives, or other forms of storage. The circuit board 108 may also be configured to provide connections to one or more peripherals (e.g., a keyboard, mouse, serial port, parallel port, Firewire/IEEE 1394a, universal serial bus (USB), Ethernet, audio). The circuit board 108 and its connected components (e.g., CPU) provide a source of the heat generated during operation of the electronic device (i.e., a heat source 122).

Another internal component within the electronic device 100 is the battery 110. In certain examples, the electronic device may include a plurality (i.e., 2 or more) of batteries. The battery 110 may be any type of battery now known or later developed. In certain examples, the battery is a secondary or rechargeable battery (e.g., a metal ion or metal air battery such as a lithium air or lithium ion battery). In some examples, the battery may be in the same plane as the motherboard (e.g., the same x-y plane, as depicted in FIG. 1). In other examples, the battery may be in a different plane from the motherboard, wherein the battery plane is parallel with the motherboard plane (e.g., the x-y plane of the battery is at a different z height from the x-y plane of the motherboard).

The electronic device 100 may include additional internal components between the display module 102 and the backing layer 106. For example, the electronic device 100 may include an active cooling source (e.g., a fan). As used herein, “active cooling” may refer to the use of forced fluid movement (e.g. fans moving air or pumps moving water) to reduce the heat of a component (e.g., a microprocessor) of the electronic device. Active cooling contrasts with “passive cooling,” which utilizes non-forced methods of cooling such as natural convection or radiation or involves reducing the speed at which a component (e.g., a microprocessor) is running to reduce the component's heat. The fan, when active, may drive air through areas or channels within the internal area of the electronic device to assist in removing heat from the electronic device.

At least one thermal management device 112 is positioned between the display module 102 and backing layer 106. The thermal management device 112 is configured to assist in removing or dissipating heat from a heat source of the electronic device (e.g., a processor or battery). In one example, the thermal management device 112 may be positioned between the circuit board 108 or battery 110 and the display module 102. In another example, as depicted in FIG. 1, the thermal management device 112 may be positioned between the circuit board 108 or battery 110 and the backing layer 106.

As depicted in FIG. 1, the thermal management device 112 includes a heat spreader 114 (e.g., a cold plate) and a heat dissipation device 116 The heat spreader 114 has a first surface 118 and second, opposite surface 120. The first surface 118 of the heat spreader 114 is positioned adjacent to or abuts a heat source 122 (e.g., the processor die) of the electronic device. At least a portion of the second surface 120 of the heat spreader 114 is metallurgically bonded with at least a portion of a surface 124 of the heat dissipation device 116 to continue the transfer of heat from the heat source 122 to the heat dissipation device 116. This arrangement may be advantageous because the heat generated from the heat source 122 (e.g., processor) during operation of the electronic device 100 may be transferred directly to the heat spreader 114, which may then be dissipated to heat dissipation device 116.

The heat spreader 114 may be made of a thermally conductive material. The thermally conductive material may have a high thermal conductivity (e.g., a thermal conductivity greater than 100 W/(m·K), 150 W/(m·K), 200 W/(m·K), 300 W/(m·K), or 400 W/(m·K)). For example, the heat spreader 114 may be copper, aluminum, gold, silver, tungsten, or an alloy thereof. In one example, the heat spreader 114 includes a copper metal or a copper alloy. In another example, the heat spreader 114 includes an aluminum metal or an aluminum alloy. In yet another example, the heat spreader 114 includes graphite.

In certain examples, the heat spreader 114 is an individual piece of thermally conductive material. In other examples, the heat spreader 114 includes a plurality of thermally conductive segments of material that are connected or joined together. The segments may be connected by soldering or sintering the segments together. In other examples, the segments may be connected through use of an intermediate adhesive layer. In yet other examples, the segments may be connected by affixing a portion of a surface of one segment against a surface of the second segment (e.g., without any adhesive or bonding).

The heat spreader 114 may be a cold plate or in the shape of a plate, wherein the first and second surfaces 118, 120 are flat surfaces. The first and second surfaces 118, 120 of the heat spreader 114 may be parallel with each other. The first and second surfaces 118, 120 may be in the shapes of similarly or differently sized ovals, circles, or quadrilaterals such as rectangles or squares. The three-dimensional shape of the heat spreader 114 may be a cuboid, cube, or cylinder.

The dimensions (e.g., length, width, height, perimeter, surface area) of the heat spreader 114 may be configurable based on the size of the electronic device 100 and the additional internal components within the electronic device 100. In certain examples, the height or thickness of the heat spreader 114 (as measured in the z-direction in FIG. 1) may be 0.01-10 mm, 0.1-5 mm, 1-5 mm, or 1-10 mm. The length and width of a section of the heat spreader 114 may be configured to be at least as long and wide as the adjacent or abutting heat source 122 (e.g., the processor or battery).

As noted above, the heat spreader 114 is metallurgically bonded with the heat dissipation device 116. As depicted in FIG. 1, the heat dissipation device 116 is a vapor chamber. Alternatively, the heat dissipation device may be a heat fin, a heat pipe, or a heat sink.

The heat dissipation device 116 may also be made of a thermally conductive material. The thermally conductive material may also have a high thermal conductivity (e.g., a thermal conductivity greater than 100 W/(m·K), 150 W/(m·K), 200 W/(m·K), 300 W/(m·K), or 400 W/(m·K)). In some examples, the thermal conductivity of the heat dissipation device 116 is less than the thermal conductivity of the heat spreader 114.

In certain examples, the heat dissipation device 116 has a higher yield strength than the heat spreader 114. This may be advantageous in avoiding plastic deformation of the heat dissipation device 116 during the metallurgical bonding with the heat spreader 114.

The heat dissipation device 116 may include titanium metal, titanium alloy, steel, stainless steel, or a combination thereof. In one example, the heat dissipation device 116 includes titanium metal or a titanium alloy. In other examples, the heat dissipation device 116 includes stainless steel.

The dimensions (e.g., length, width, height, perimeter, surface area) of the heat dissipation device 116 may also be configurable based on the size of the electronic device 100 and the additional internal components within the electronic device 100. In certain examples, the dimensions of the heat dissipation device 116 are configurable based on the size of the metallurgically bonded heat spreader 114. For example, the length and width of a section of the heat dissipation device 116 may be configured to be at least as long and wide as the surface of the metallurgically bonded heat spreader 114.

Furthermore, the height or thickness of a plate or layer of the heat dissipation device 116 that is bonded with the heat spreader 114 may be less than the height or thickness of the heat spreader 114 (i.e., as measured in the z-direction direction as depicted in FIG. 1). The height or thickness of a layer or plate of the heat dissipation device 116 may be 0.01-10 mm, 0.1-5 mm, 0.1-2 mm, or 0.5-1 mm.

Specifically, the height or thickness of the metal plate of the vapor chamber is less than the height or thickness of the heat spreader to which the metal plate is metallurgically bonded. In one example, the height of the heat spreader is approximately 5 mm and the height of the plate of the vapor chamber to which it is metallurgically bonded is approximately 1 mm.

Having a thinner heat dissipation device is possible because the strength of the heat dissipation device is greater than the strength of the heat spreader. As such, a thinner metal may be used while providing a similar or greater structural support. As noted above, this is advantageous in combining a heat spreader having a softer, more conductive metal (e.g., copper) to spread the heat from the heat source with a stronger, lighter metal (e.g., titanium) for further dissipation of the heat. This allows for the construction of a thinner, lighter heat dissipation device relative to copper while maintaining or improving the thermal performance of the device. This may lead to the construction of an electronic device with a more powerful microprocessor, a thinner or lighter electronic device, a higher processing speed, or a combination thereof when compared to a similar electronic device without one or more of the improved heat dissipation features.

For example, the electronic device 100 may have a maximum desirable surface or touch temperature (e.g., 48° C.). With the improved heat dissipation features described herein, the processor may be able to process more power (e.g., Watts) without exceeding the touch temperature. In certain examples, with the improved heat dissipation, the electronic device may be able to process at least an additional 1 Watt, 2 Watts, 3 Watts, 4 Watts, 5 Watts, or 10 Watts of power without exceeding the maximum touch temperature when compared to a similar device without the thermal management device disclosed herein.

The electronic device 100 may alternatively or additionally have a maximum desirable junction temperature (e.g., 90° C.) at the location of the heat source and heat spreader. With the improved heat dissipation feature described herein, the processor may be able to process more power (e.g., Watts) without exceeding the junction temperature. In certain examples, with the improved heat dissipation, the electronic device may be able to process at least an additional 1 Watt, 2 Watts, 3 Watts, 4 Watts, 5 Watts, or 10 Watts of power without exceeding the maximum junction temperature when compared to a similar device without the thermal management device disclosed herein.

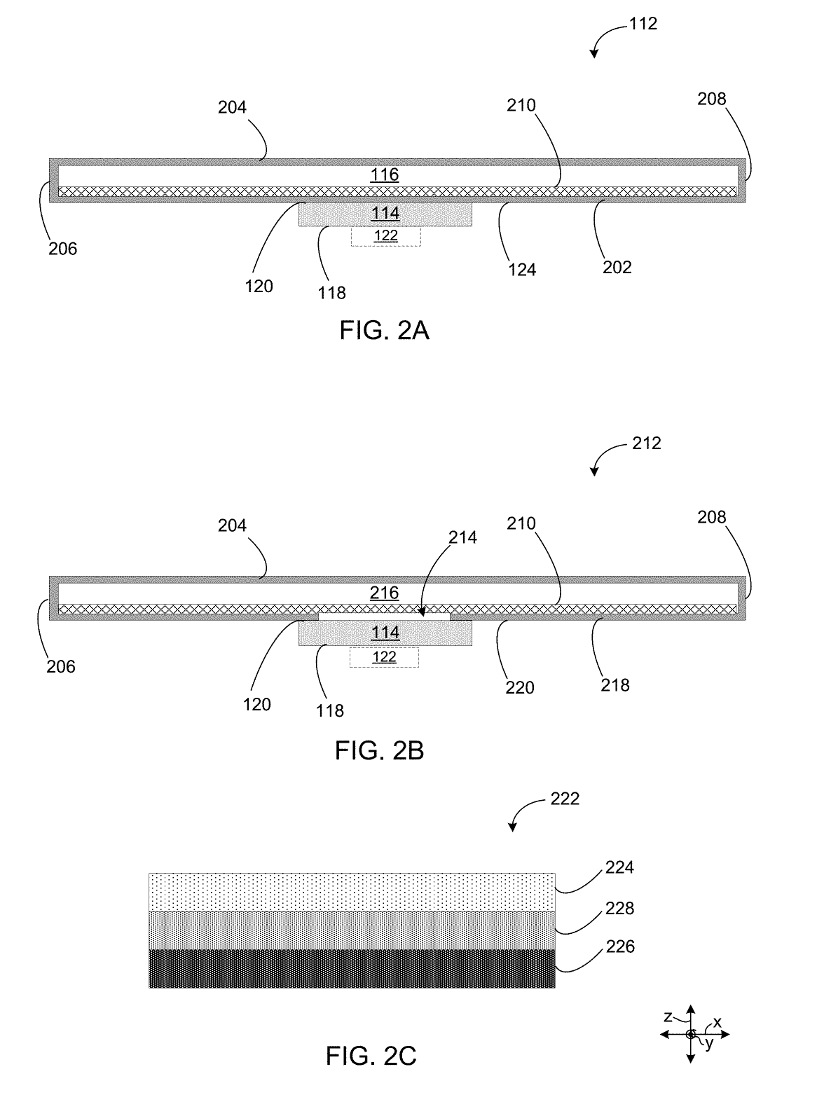

FIG. 2A depicts a more detailed view of the thermal management device 112 of FIG. 1. The thermal management device 112 includes a heat spreader 114 (e.g., a cold plate) and a vapor chamber 116. The heat spreader 114 has a first surface 118 and second, opposite surface 120. The first surface 118 of the heat spreader 114 is positioned adjacent to or abuts a heat source 122 (e.g., the processor die) of the electronic device. At least a portion of the second surface 120 of the heat spreader 114 is metallurgically bonded with at least a portion of a surface 124 of the vapor chamber 116 to continue the transfer of heat from the heat source 122 to the vapor chamber 116.

As depicted in FIG. 2A, the vapor chamber 116 includes a first plate 202, a second plate 204, and a plurality of perimeter frames 206, 208 positioned between the first plate 202 and the second plate 204. The vapor chamber 116 also includes a wicking layer 210 positioned between the first plate 202, the second plate 204, and the perimeter frames 206, 208.

In certain examples, the vapor chamber is not formed until after the heat spreader 114 is metallurgically bonded with the first plate 202. This may be advantageous in avoiding deformation of the perimeter frames, second plate, and/or wicking layer during the bonding process. Additionally, in some welding techniques, it may be infeasible to have a fully formed vapor chamber welded to the heat spreader 114.

Therefore, in some examples, the first plate 202 is metallurgically bonded with the heat spreader 114 before formation of the remainder of the vapor chamber. Following the metallurgical bonding, the perimeter frames 206, 208 may be affixed to the first plate 202. A wicking layer 210 may then be inserted into the internal cavity of the partially constructed chamber. Finally, the second plate 204 may be installed to finish formation of the vapor chamber.

FIG. 2B depicts an additional example of a thermal management device 212 having a modified vapor chamber 216. The device in FIG. 2B is similar to FIG. 2A, except that a hole or opening 214 is provided in the first plate 218 of the vapor chamber 216 at the interface between the vapor chamber 216 and the heat spreader 114.

In this example, the first surface 118 of the heat spreader 114 is positioned adjacent to or abuts a heat source 122 (e.g., the processor die) of the electronic device. At least a portion of the second surface 120 of the heat spreader 114 is metallurgically bonded with at least a portion of a surface 220 of the vapor chamber 216 to continue the transfer of heat from the heat source 122 to the vapor chamber 216. In this example, the metallurgical bond is positioned around the perimeter of the opening 214 in the first plate 218. Such an arrangement may be advantageous in providing a more direct path of heat transfer from the heat spreader to the wicking layer 210 of the vapor chamber 216.

FIG. 2C depicts an example 222 of a metallurgical bond between two components 224, 226 of a thermal management device. In this example, the first metal plate 224 is coupled with a second metal plate 226 at an interface 228. The interface represents an area between the two metal plates were the composition is a mixture of the first metal plate 224 and the second metal plate 226. In other words, the interface 228 may represent a mixture of two dissimilar metal compositions. Through the metallurgical bonding process, the interface 228 is free of voids, oxide films, or discontinuities.

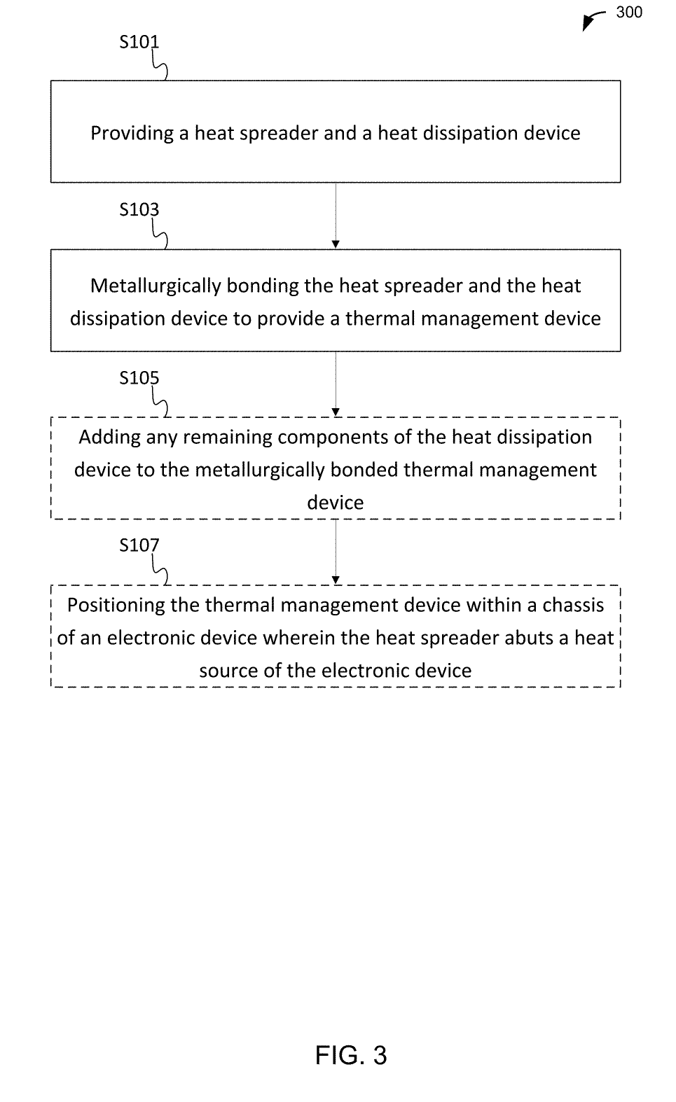

FIG. 3 depicts an exemplary method 300 for making a thermal management device. At act S101, a heat spreader and a heat dissipation device are provided. As noted above, the heat spreader may be a copper plate. The heat dissipation device may be a vapor chamber, heat sink, heat fin, or heat pipe. In one example, the heat spreader is a copper plate, and the heat dissipation device is a vapor chamber having a titanium frame.

At act S103, the heat spreader is metallurgically bonded with the heat dissipation device. The bonding process may be performed by magnetic pulse welding, explosion welding, friction welding, or pulsed laser welding.

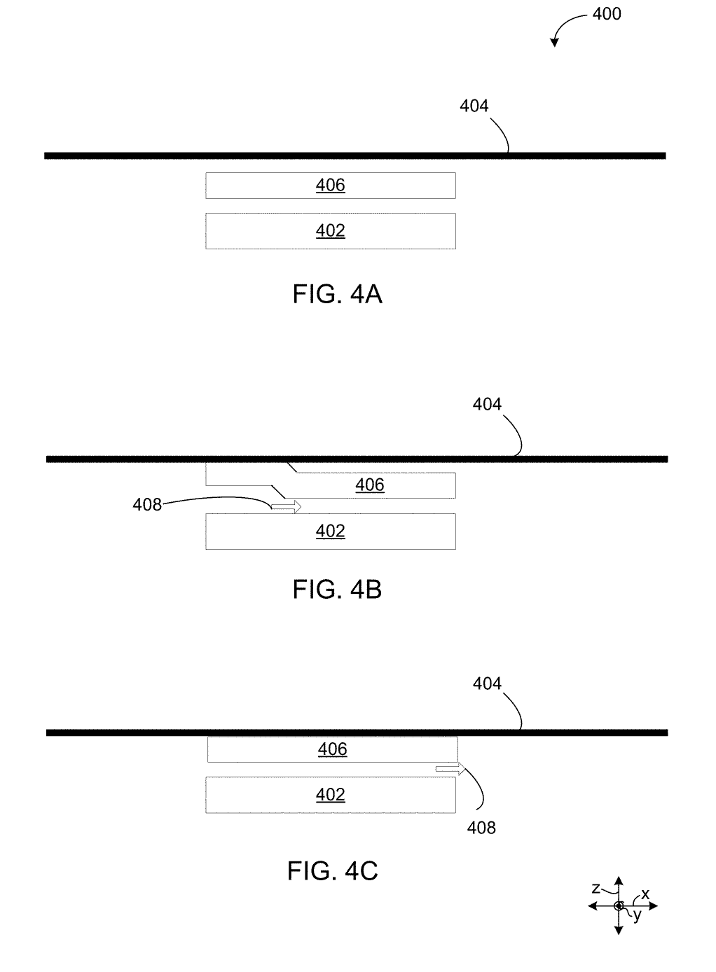

As noted above, magnetic pulse welding involves a process of forming a high-quality weld of similar and dissimilar metals in microseconds without the need for shielding gases or welding consumables. This process is advantageous in avoiding formation of a brittle intermetallic phase between the two metals. An example of the magnetic pulse welding process is further described in FIGS. 4A-4C.

Friction welding may refer to a solid-state welding process that generates heat through mechanical friction between two metals in relative motion to one another, with the addition of a lateral force called “upset” to plastically displace and fuse the materials. Because no melting occurs, friction welding is not a fusion welding process in the traditional sense, but more of a forge welding technique. In one example, a spin welding technique is used. The technique consists of fixing one metal plate in place and rotating the second metal plate (e.g., about a flywheel). The second metal plate is spun at a high rate of rotation using a motor. Once the plate is spinning at a proper speed, the motor is removed and the two metal places are forced together under pressure. The force is kept on the two plates until the spinning stops, allowing the weld to set. In another example involves a linear friction welding technique, wherein the moving metal plate oscillates laterally instead of spinning. Additional examples of friction welding include friction surfacing, linear vibration welding, or orbital friction welding. Each of these welding techniques is advantageous in boding two dissimilar metals without melting either metal surface.

Explosion welding may refer to a solid-state welding process where welding is accomplished by accelerating one of the components at extremely high velocity using chemical explosives. The chemical explosive may be positioned on or near a surface of one or both metal plates. Like the magnetic pulse welding discussed below in FIGS. 4A-C, the chemical reaction or explosion may cause one plate to fly into the other plate. This welding technique is advantageous in bonding two dissimilar metals together without melting either metal surface. Instead, a surface of the metal plate undergoes a plastic deformation during the bonding process.

Pulsed laser welding may refer to a process where two metals are joined together using an intermittent or pulsed laser beam. The pulsed beam provides a concentrated heat source, allowing for narrow, deep welds and high welding rates. This may allow for formation of a metal rivet-like bonding between the two metals, wherein the first metal flows into the second metal at the location of the applied pulsed laser beam.

The beam may be pulsed or turned on an off at a predefined frequency of time. The energy of a beam, the power of the beam, the peak power of the beam, the frequency of the pulse, the duration of the pulse, and the surface area of the applied pulse are all variables that may be optimized to create an effective metallurgical bond.

In certain examples, the laser is a solid-state laser such as a ruby laser or a neodymium-doped yttrium aluminum garnet (Nd:YAG) laser. The laser may emit light having an infrared wavelength (e.g., 1064 nm).

In some examples, the pulse energy of each beam is 0.01-100 millijoules (mJ), 0.1-10 mJ, 0.1-1 mJ, less than 10 mJ, or less than 1 mJ. The peak power of each beam may be 1-20 kW or 5-10 kW. The average power of each beam may be 1W-1kW, 1-100 W, 1-10 W, less than 1 kW, less than 100 W, or less than 10 W. The frequency of the pulsed lasers may be 10-1000 kilohertz (kHz), 100-1000 kHz, at least 10 kHz, at least 100 kHz, or at least 1000 kHz. The pulse duration of each beam may be 0.1-100 nanoseconds (ns), 1-10 ns, 1-5 ns, 1 ns, less than 10 ns, less than 5 ns, or less than 1 ns.

In certain examples, the pulsed laser welding process is a spot welding process such that the metallurgical bond between the two metals is only present in certain locations. In other words, the pulsed laser beam may be applied to a fraction of a surface of one metal component positioned adjacent to the second metal component. The fraction of the adjoining surfaces subjected to the pulsed laser welding may be 1-50%, 5-25%, 10-20%, less than 50%, less than 25%, less than 20%, less than 10%, less than 5%, or less than 1% of the adjoining surfaces of the two metals.

At act S105, additional components of the heat dissipation device may be added to the metallurgically bonded thermal management device. For example, a vapor chamber may be fully constructed following the metallurgical bonding of the heat spreader with a portion (e.g., plate) of the vapor chamber. In this process, a perimeter frame may be bonded to the plate of the vapor chamber at each edge of the vapor chamber. Additionally, a wicking layer may be positioned between the perimeter frames and adjacent to the plate of the vapor chamber. Further, an additional plate may be attached to the perimeter frames to enclose the wicking layer and form a chamber of the vapor chamber.

At act S107, the thermal management device may be installed within an electronic device. The thermal management device may be positioned such that the heat spreader is adjacent to or abuts a heat source of the electronic device (such as a processor or battery).

FIGS. 4A, 4B, and 4C depict various stages of making a thermal management device in accordance with a magnetic pulse welding example 400.

FIG. 4A depicts an actuator 402, heat dissipation plate 404, and heat spreader 406. In terms of magnetic pulse welding, the heat dissipation plate 404 is the “target” and the heat spreader is the “flyer.”

As depicted in FIG. 4B, the actuator 402 applies an electromagnetic force (e.g., an eddy current 408) to cause the heat spreader (flyer) 406 to move into the heat dissipation plate (target) 404 at a high impact velocity (e.g., 300 m/s). The eddy current 408 is depicted as moving along the y-axis, in a direction parallel with the flyer 406 and target 404. The heat spreader 406 and heat dissipation plate 404 are welded together, wherein a metallurgical bond is formed between the two components (such as represented in FIG. 2C). This joining occurs by plastic deformation of the flyer and, under controlled conditions, an atomic bond in a solid-state weld is created between the two materials. The controllable conditions include, for example, the discharge energy, standoff distance between the two plates, impact velocity, magnetic pressure, and/or collision angle. These conditions may be modified based on the type and shape of materials being bonded together.

Finally, in FIG. 4C, after the eddy current 408 of the actuator 402 has moved past the entire length of the heat spreader (flyer) 406, the two components are fully metallurgically bonded together. This process is advantageous in creating a solid-state weld without an external heat source and no thermal distortions.

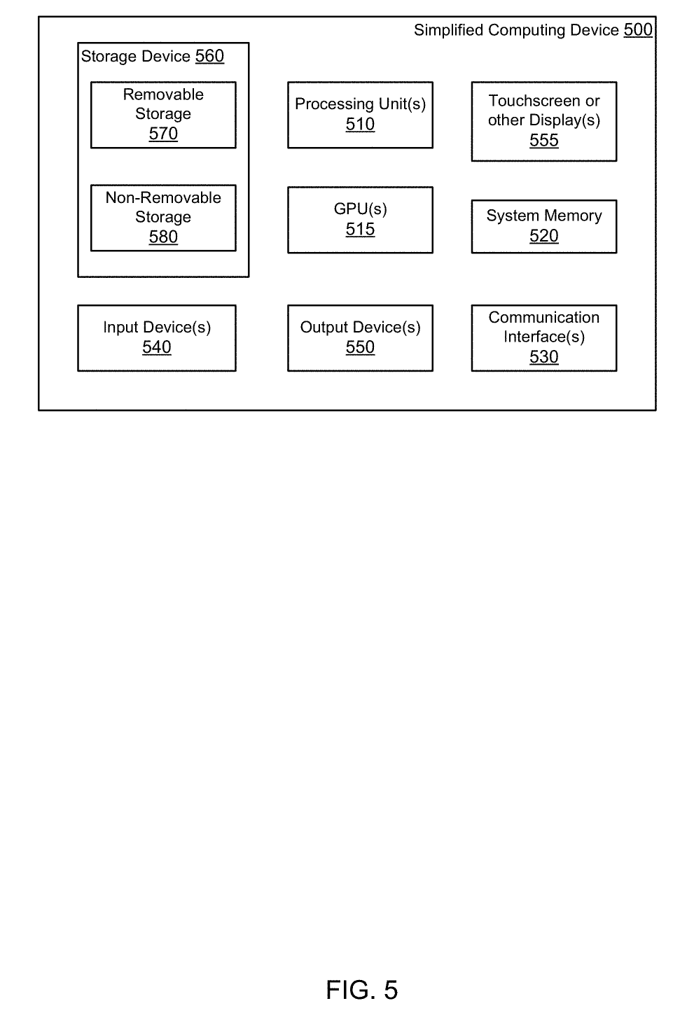

Regarding FIG. 5, a thermal management device as described above may be incorporated within an exemplary computing environment 500. The computing environment 500 may correspond with one of a wide variety of computing devices, including, but not limited to, personal computers (PCs), server computers, tablet and other handheld computing devices, laptop or mobile computers, communications devices such as mobile phones, multiprocessor systems, microprocessor-based systems, set top boxes, programmable consumer electronics, network PCs, minicomputers, mainframe computers, or audio or video media players. In certain examples, the computing device may be a wearable electronic device, wherein the device may be worn on or attached to a person's body or clothing. The wearable device may be attached to a person's shirt or jacket; worn on a person's wrist, ankle, waist, or head; or worn over their eyes or ears. Such wearable devices may include a watch, heart-rate monitor, activity tracker, or head-mounted display.

The computing environment 500 has sufficient computational capability and system memory to enable basic computational operations. In this example, the computing environment 500 includes one or more processing unit(s) 510, which may be individually or collectively referred to herein as a processor. The computing environment 500 may also include one or more graphics processing units (GPUs) 515. The processor 510 and/or the GPU 515 may include integrated memory and/or be in communication with system memory 520. The processor 510 and/or the GPU 515 may be a specialized microprocessor, such as a digital signal processor (DSP), a very long instruction word (VLIW) processor, or other microcontroller, or may be a general-purpose central processing unit (CPU) having one or more processing cores. The processor 510, the GPU 515, the system memory 520, and/or any other components of the computing environment 500 may be packaged or otherwise integrated as a system on a chip (SoC), application-specific integrated circuit (ASIC), or other integrated circuit or system.

The computing environment 500 may also include other components, such as, for example, a communications interface 530. One or more computer input devices 540 (e.g., pointing devices, keyboards, audio input devices, video input devices, haptic input devices, or devices for receiving wired or wireless data transmissions) may be provided. The input devices 540 may include one or more touch-sensitive surfaces, such as track pads. Various output devices 550, including touchscreen or touch-sensitive display(s) 555, may also be provided. The output devices 550 may include a variety of different audio output devices, video output devices, and/or devices for transmitting wired or wireless data transmissions.

The computing environment 500 may also include a variety of computer readable media for storage of information such as computer-readable or computer-executable instructions, data structures, program modules, or other data. Computer readable media may be any available media accessible via storage devices 560 and includes both volatile and nonvolatile media, whether in removable storage 570 and/or non-removable storage 580. Computer readable media may include computer storage media and communication media. Computer storage media may include volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by the processing units of the computing environment 500.

While the present claim scope has been described with reference to specific examples, which are intended to be illustrative only and not to be limiting of the claim scope, it will be apparent to those of ordinary skill in the art that changes, additions and/or deletions may be made to the disclosed embodiments without departing from the spirit and scope of the claims.

The foregoing description is given for clearness of understanding only, and no unnecessary limitations should be understood therefrom, as modifications within the scope of the claims may be apparent to those having ordinary skill in the art.

### Claim Support Section

In a first embodiment, a thermal management device comprises a heat spreader having a first surface and a second surface, wherein the first surface of the heat spreader is configured to be positioned adjacent to a heat source of the electronic device; and a heat dissipation device configured to dissipate heat from the heat source, wherein at least a portion of the second surface of the heat spreader is metallurgically bonded with at least a portion of a surface of the heat dissipation device.

In a second embodiment, an electronic device comprises a display module; a backing layer; a processor positioned between the display module and the backing layer; a heat spreader positioned between the display module and the backing layer, the heat spreader having a first surface and a second surface, wherein the first surface of the heat spreader abuts a surface of the processor; and a heat dissipation device configured to dissipate heat from the processor, wherein at least a portion of the second surface of the heat spreader is metallurgically bonded with at least a portion of a surface of the heat dissipation device.

In a third embodiment, a method of making a thermal management device for an electronic device comprises: providing a heat spreader and a heat dissipation device, wherein the heat spreader is a metallic cold plate and the heat dissipation device is a heat fin, a heat tube, a heat sink, or a plate of a vapor chamber; and metallurgically bonding at least a portion of a surface of the heat spreader with at least a portion of a surface of the heat dissipation device, wherein no additional composition or material is used to bond the heat spreader and the heat dissipation device other than a composition of the heat spreader and a composition of the heat dissipation device.

In a fourth embodiment, with reference to any of embodiments 1-3, the heat spreader comprises copper metal, copper alloy, aluminum metal, aluminum alloy, or a combination thereof.

In a fifth embodiment, with reference to any of embodiments 1-4, the heat dissipation device is a vapor chamber.

In a sixth embodiment, with reference to any of embodiments 1-5, the vapor chamber comprises an opening in the surface, wherein the heat spreader is metallurgically bonded with the surface of the vapor chamber around a perimeter of the opening, and wherein the heat spreader is configured to dissipate a portion of the heat through the opening to a wicking layer of the vapor chamber.

In a seventh embodiment, with reference to any of embodiments 1-6, the heat dissipation device is a heat fin, a heat pipe, or heat sink.

In an eighth embodiment, with reference to any of embodiments 1-7, the heat dissipation device comprises titanium metal, titanium alloy, stainless steel, or a combination thereof.

In a ninth embodiment, with reference to any of embodiments 1-8, the heat spreader and the heat dissipation device are metallurgically bonded via a magnetic pulse weld, an explosion weld, or a friction weld.

In a tenth embodiment, with reference to any of embodiments 1-9, the heat spreader is copper metal, and the heat dissipation device is a vapor chamber comprising titanium metal.

In an eleventh embodiment, with reference to any of embodiments 1-10, the vapor chamber comprises an opening in the surface, the heat spreader is metallurgically bonded with the surface of the vapor chamber around a perimeter of the opening, and the heat spreader is configured to dissipate a portion of the heat through the opening to a wicking layer of the vapor chamber.

In a twelfth embodiment, with reference to any of embodiments 1-11, the metallurgically bonding is performed by magnetic pulse welding.

In a thirteenth embodiment, with reference to any of embodiments 1-11, the metallurgically bonding is performed by explosion welding, friction welding, or pulsed laser welding.

In a fourteenth embodiment, with reference to any of embodiments 1-13, a perimeter frame is bonded at each edge of the plate of the vapor chamber; a wicking layer is provided between the perimeter frames and adjacent to the plate of the vapor chamber; and an additional plate is attached to the perimeter frames to enclose the wicking layer and form a chamber of the vapor chamber.

What is claimed is:

1. A thermal management device comprising:
a heat spreader having a first surface and a second surface, wherein the first surface of the heat spreader is configured to be positioned adjacent to a heat source of an electronic device; and
a heat dissipation device configured to dissipate heat from the heat source,
wherein at least a portion of the second surface of the heat spreader is metallurgically bonded with at least a portion of a surface of the heat dissipation device.

2. The thermal management device of claim 1, wherein the heat spreader comprises copper metal, copper alloy, aluminum metal, aluminum alloy, or a combination thereof.

3. The thermal management device of claim 1, wherein the heat dissipation device is a vapor chamber.

4. The thermal management device of claim 3, wherein the vapor chamber comprises an opening in the surface,
wherein the heat spreader is metallurgically bonded with the surface of the vapor chamber around a perimeter of the opening, and
wherein the heat spreader is configured to dissipate a portion of the heat through the opening to a wicking layer of the vapor chamber.

5. The thermal management device of claim 1, wherein the heat dissipation device is a heat fin, a heat pipe, or heat sink.

6. The thermal management device of claim 1, wherein the heat dissipation device comprises titanium metal, titanium alloy, stainless steel, or a combination thereof.

7. The thermal management device of claim 1, wherein the heat spreader and the heat dissipation device are metallurgically bonded via a magnetic pulse weld, an explosion weld, a friction weld, or a pulsed laser weld.

8. The thermal management device of claim 1, wherein the heat spreader is copper metal, and
wherein the heat dissipation device is a vapor chamber comprising titanium metal.

9. An electronic device comprising:
a display module;
a backing layer;
a processor positioned between the display module and the backing layer;
a heat spreader positioned between the display module and the backing layer, the heat spreader having a first surface and a second surface, wherein the first surface of the heat spreader abuts a surface of the processor; and
a heat dissipation device configured to dissipate heat from the processor,
wherein at least a portion of the second surface of the heat spreader is metallurgically bonded with at least a portion of a surface of the heat dissipation device.

10. The electronic device of claim 9, wherein the heat spreader comprises copper metal, copper alloy, aluminum metal, aluminum alloy, or a combination thereof, and
wherein the heat dissipation device comprises titanium metal, titanium alloy, stainless steel, or a combination thereof.

11. The electronic device of claim 9, wherein the heat dissipation device is a vapor chamber.

12. The electronic device of claim 11, wherein the vapor chamber comprises an opening in the surface,
wherein the heat spreader is metallurgically bonded with the surface of the vapor chamber around a perimeter of the opening, and
wherein the heat spreader is configured to dissipate a portion of the heat through the opening to a wicking layer of the vapor chamber.

13. The electronic device of claim 9, wherein the heat spreader and the heat dissipation device are metallurgically bonded via a magnetic pulse weld, an explosion weld, a friction weld, or a pulsed laser weld.

14. The electronic device of claim 9, wherein the heat spreader is copper metal, and
wherein the heat dissipation device is a vapor chamber comprising titanium metal.

15. A method of making a thermal management device for an electronic device, the method comprising:
providing a heat spreader and a heat dissipation device, wherein the heat spreader is a metallic cold plate and the heat dissipation device is a heat fin, a heat tube, a heat sink, or a plate of a vapor chamber; and
metallurgically bonding at least a portion of a surface of the heat spreader with at least a portion of a surface of the heat dissipation device, wherein no additional composition or material is used to bond the heat spreader and the heat dissipation device other than a composition of the heat spreader and a composition of the heat dissipation device.

16. The method of claim 15, wherein the metallurgically bonding is performed by magnetic pulse welding.

17. The method of claim 15, wherein the metallurgically bonding is performed by explosion welding, friction welding, or pulsed laser welding.

18. The method of claim 15, wherein the heat spreader comprises copper metal, copper alloy, aluminum metal, aluminum alloy, or a combination thereof, and
wherein the heat dissipation device comprises titanium metal, titanium alloy, stainless steel, or a combination thereof.

19. The method of claim 15, wherein the plate of the vapor chamber comprises an opening in the plate,
wherein the heat spreader is metallurgically bonded with the surface of the vapor chamber around a perimeter of the opening, and
wherein the heat spreader is configured to dissipate a portion of the heat through the opening to a wicking layer of the vapor chamber.

20. The method of claim 15, further comprising, following the metallurgical bonding:
bonding a perimeter frame at each edge of the plate of the vapor chamber;
providing a wicking layer between the perimeter frames and adjacent to the plate of the vapor chamber; and
attaching an additional plate to the perimeter frames to enclose the wicking layer and form a chamber of the vapor chamber.
